(19) United States
(12) Patent Application Publication
(10) Pub. No.: US 2025/0072047 A1
(43) Pub. Date: Feb. 27, 2025

(54) Trench MOSFET and manufacturing method thereof

(71) Applicant: Hangzhou Silicon-Magic Semiconductor Technology Co.,Ltd, Hangzhou (CN)

(72) Inventors: Yanggang OU, Hangzhou (CN); Jiakun WANG, Hangzhou (CN)

(73) Assignee: Hangzhou Silicon-Magic Semiconductor Technology Co.,Ltd, Hangzhou (CN)

(21) Appl. No.: 18/801,861

(22) Filed: Aug. 13, 2024

(30) Foreign Application Priority Data
Aug. 23, 2023 (CN) 2023110719994

(51) Int. Cl. H01L 29/78; H01L 29/06; H01L 29/417; H01L 29/66

(52) U.S. Cl. CPC H01L 29/7813; H01L 29/0684; H01L 29/41766; H01L 29/66727; H01L 29/66734

(57) ABSTRACT

A semiconductor device includes a current spreading layer, a gate trench, a gate electrode, a first body region, a first source region, a second body region and a second source region. The first body region is beneath and in contact with the gate trench. The first source region is formed in the first body region. The second body region extends from a first surface of the current spreading layer into the current spreading layer and adjoins a first sidewall of the gate trench. The second source region is formed in the second body region and adjoins the first sidewall of the gate trench.

### CROSS-REFERENCE TO RELATED APPLICATION

This application claims the benefit of Chinese Patent Application No. 202311071999.4, filed on Aug. 23, 2023, which is incorporated herein by reference in its entirety.

### TECHNICAL FIELD

The present disclosure relates to the field of power electronics, and more particularly to trench MOSFET and manufacturing method thereof.

### BACKGROUND

Planar SiC (Silicon Carbide) MOSFET (Metal Oxide Semiconductor Field Effect Transistor) usually has high on-resistance due to the JFET (Junction Field Effect Transistor) effect. The trench MOSFET is widely used in the power electronic devices for its high input impedance, small driving current, fast switching speed and good high temperature characteristics.

For the trench MOSFET, improving the on-state characteristics of the MOSFET to reduce the die size is important.

### SUMMARY

The present disclosure provides a trench MOSFET and the manufacturing method thereof. The embodiments of the present disclosure enhance the conduction characteristics of the trench MOSFET by introducing a vertical channel region at the side of the gate trench and a lateral channel region at the bottom of the gate trench. The vertical channel region and the lateral channel region provides more conduction regions within a limited area, which maximizes the use of semiconductor materials and reduce the die size.

The embodiments of the present invention are directed to a semiconductor device including a current spreading layer, a gate trench, a gate electrode, a first body region, a first source region, a second body region and a second source region. The current spreading layer has a first surface and a second surface opposite to the first surface along a vertical direction. The gate trench is formed in the current spreading layer. The gate trench vertically extends from the first surface of the current spreading layer into the current spreading layer. The gate electrode fills in the gate trench with a gate dielectric layer in between for insulation. The first body region is beneath the gate trench and is in contact with the gate trench. The first source region is formed in the first body region. The second body region extends from the first surface of the current spreading layer into the current spreading layer and adjoins a first sidewall of the gate trench. The second source region is formed in the second body region. The second source region adjoins the first sidewall of the gate trench.

The embodiments of the present invention are directed to a semiconductor device including a current spreading layer, a plurality of gate trenches, a plurality of gate electrodes, a plurality of first body regions, a plurality of first source regions, a plurality of second body regions, a plurality of second source regions, a plurality of source trenches and a plurality of source electrodes. The current spreading layer having a first surface and a second surface opposite to the first surface along a vertical direction. The plurality of gate trenches are formed in the current spreading layer. The plurality of gate trenches vertically extend from the first surface of the current spreading layer into the current spreading layer. The plurality of gate electrodes fills in the plurality of gate trenches respectively with a gate dielectric layer in between for insulation; The plurality of first body regions are beneath the plurality of gate trenches respectively, and each one of the plurality of first body regions is in contact with the respective one of the plurality of gate trenches. The plurality of first source regions are formed in the plurality of first body region respectively. The plurality of second body regions extend from the first surface of the current spreading layer into the current spreading layer. Each one of plurality of second body regions adjoins a first sidewall of the respective one of the plurality of gate trenches. The plurality of second source regions are formed in the plurality of second body regions respectively. Each one of the plurality of second source regions adjoins the first sidewall of the respective one of the plurality of gate trenches. The plurality of source trenches extend from the first surface of the current spreading layer into the current spreading layer. Each one of the plurality of source trenches is formed between two neighboring gate trenches. The plurality of source electrodes fills in the plurality of source trenches respectively. Each one of the plurality of source electrodes is insulated from sidewalls of the respective one of the plurality of source trenches with source dielectric layers. The plurality of doping regions are under the plurality of source trenches respectively.

The embodiments of the present invention are directed to a semiconductor device manufacturing method including forming a substrate, an epitaxial layer, a current spreading layer, source trenches, first body regions, second body regions, first source regions, second source regions, buried layers, dielectric layers, gate trenches, gate electrode, source electrode, interlayer dielectric layers, a source contact and a drain contact. The epitaxial is formed on the substrate. The current spreading layer is formed on the epitaxial layer. The source trenches are formed in the current spreading layer. The first body regions are formed in the mesas between the neighboring first trenches and source trenches. The second body regions are formed at the bottom of the first trenches. The first source regions are formed in the first body regions. The second source regions are formed in the second body regions. The buried layers are formed at the bottom of the source trenches. The dielectric layers are formed on top of a surface of the semiconductor device which is distanced from the substrate. Then the dielectric layers at the bottom of the source trenches are etched away to expose the doping regions. The dielectric layers on the sidewalls of the source trenches server as the source dielectric layers. The dielectric layers in the first trenches are etched to form the gate trenches. The dielectric layers in the gate trenches serve as the gate dielectric layers. The gate electrodes are formed in the gate trenches. The source electrodes are formed in the source trenches. The interlayer dielectric layers covers the gate electrodes and the gate dielectric layers. The source contact electrically connects the first source regions and the second source regions. The drain contact electrically connects the substrate.

### BRIEF DESCRIPTION OF FIGURES

The present disclosure can be further understood with reference to following detailed description and appended drawings, wherein like elements are provided with like reference numerals. These drawings are only for illustration purpose, thus may only show part of the devices and are not necessarily drawn to scale. It is obvious that the drawings described below are some implementations of the present disclosure, and those skilled in the art would also obtain other drawings on the basis of these drawings, without involving any inventive skill.

FIG. 1 shows a cross-sectional view of a Trench MOSFET 100in accordance with an embodiment of the present disclosure;

FIG. 2 shows a cross-sectional view of a Trench MOSFET in accordance with an embodiment of the present disclosure; and

FIGS. 3a to 3h illustrate cross-sectional views of a trench MOSFET at different steps of the manufacturing process in accordance with an embodiment of the present disclosure.

The use of the same reference label in different drawings indicates the same or like components.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms.

The terms “having”, “containing”, “including”, “comprising” and the like are open, and the terms indicate the presence of stated structures, elements or features but do not preclude additional elements or features. The articles “a”, “an” and “the” are intended to include the plural as well as the singular, unless the context clearly indicates otherwise.

The Figures illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations. Unless specifically noted below, portions of the semiconductor device may include materials well known to those skilled in the art. Semiconductor materials include, for example, III-V group semiconductors such as gallium arsenide (GaAs), gallium nitride (GaN), and the like, IV-IV group semiconductors such as silicon carbide (SiC), and the like, II-VI compound semiconductors such as cadmium sulfide (CdS), cadmium telluride (CdTe), and the like, and IV group semiconductors such as silicon (Si), germanium (Ge), and the like. The gate electrode may consist of or contain, as main constituent(s), aluminum (AI), copper (Cu), or alloys of aluminum or copper, for example AlSi, AlCu or AlSiCu. According to other embodiments, at least one of the gate electrodes may contain, as main constituents(s), nickel (Ni), tin (Sn), titanium (Ti), tungsten (W), tantalum (Ts), vanadium (V), silver (Ag), gold (Au), platinum (Pt), and/or palladium (Pd). For example, at least one of the gate load electrodes may include two or more sub-layers, wherein each sub-layer contains one or more of Ni, Sn, Ti, V, Ag, Au, Pt, W, and Pd as main constituent(s), e.g., a silicide, a nitride and/or an alloy. The gate dielectric may include SiO2. The gate dielectric may include or may consist of a semiconductor oxide, or a material having a dielectric constant greater than SiO2, including, for example, oxides, nitrides, nitrogen oxides, silicates, aluminates, titanates. Moreover, the gate dielectric may include not only materials known to those skilled in the art, but also materials developed in the future for use of insulation.

In the illustrated embodiments and for the following description, the first conductivity type is n-type and the second conductivity type is p-type. Similar considerations as outlined below apply to embodiments with the first conductivity type being p-type and the second conductivity type being n-type. By implanting n-type dopants, like P or As, into a semiconductor layer, n-type layer could be formed. By implanting p-type dopants, like B, into a semiconductor layer, p-type layer could be formed.

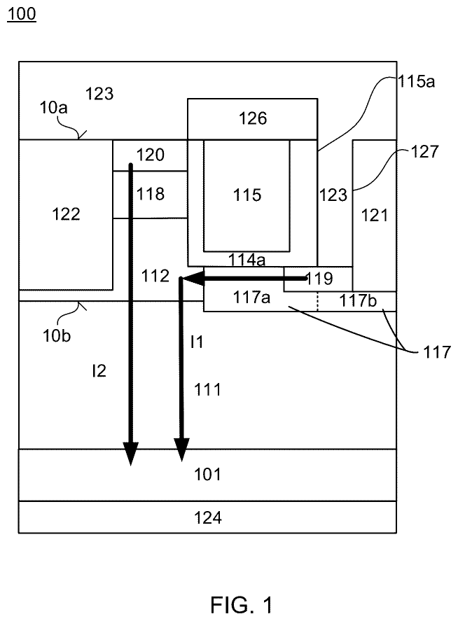

FIG. 1 shows a cross-sectional view of a trench MOSFET 100 in accordance with an embodiment of the present disclosure. The trench MOSFET 100 includes a substrate 101, an epitaxial layer 111 disposed on the substrate 101, and a current spreading layer (CSL) 112 disposed on the epitaxial layer 111. The current spreading layer has a first surface 10a and a second surface 10b which is opposite to the first surface 10a in a vertical direction. The second surface 10b is in contact with the epitaxial layer 111. The substrate 101 serves as a drain region of the trench MOSFET 100. The epitaxial layer 111 serves as a drift region of the trench MOSFET 100. The substrate 101, the epitaxial layer 111, and the current spreading layer 102 have a first conductivity type. In one embodiment, the substrate 101 is n-type with a high doping level, the epitaxial layer 111 is n-type with a low doping level, and the current spreading layer 112 is n-type with a high doping level, such that to reduce an on-resistance of the trench MOSFET 100.

The trench MOSFET 100 includes a gate trench 115a, a gate dielectric layer 114a disposed within the gate trench 115a, and a gate electrode 115. The gate trench 115a extends from the first surface 10a of the current spreading layer 112 into the current spreading layer 112. The gate electrode 115 is arranged in the gate trench 115a and is insulated from the sidewalls and the bottom of the gate trench 115a by the gate dielectric layer 114a.

As shown in the embodiment of FIG. 1, the trench MOSFET 100 includes a first body region 117, a second body region 118, a first source region 119, a second source region 120, a first shielding region 121, and a second shielding region 122. The first source region 119 and the second source region 120 have the first conductivity type. The first body region 117, the second body region 118, the first shielding region 121, and the second shielding region 122 have the second conductivity type.

The first body region 117 includes a first portion 117a disposed under the gate trench 115a and a second portion 117b adjoining the first portion 117a. The first portion 117a and the second portion 117b are connected to form the first body region 117. The first portion 117a is formed in the vertical projection of the gate trench 115a. The extension of the first portion 117a distanced from the second portion 117b stopes before the vertical plane defined by the sidewall of the gate electrode 115 which adjoins the second source region 120, such that the electronic conduction path is not blocked by the second portion 117b. In other words, the first portion 117a of the first body region 117 covers a part of the bottom of the gate trench 115a, leaving at least a portion of the gate dielectric layer at the bottom of the gate trench 115a directly contacting the current spreading layer 112 under gate trench 115a. In the embodiment of FIG. 1, the first portion 117a of the first body region 117 is under the gate trench 115a to form the lateral channel for electronic conduction, and the second portion 117b connects the first shielding region 121.

In the embodiment of FIG. 1, a bottom side of the first body region 117 has a larger vertical distance to the first surface 10a of the trench MOSFET 100 than a bottom side of the current spreading layer 112, and extends into the epitaxial layer 111. In some embodiments, the bottom side of the first body region 117 has a smaller vertical distance to the first surface 10a of the trench MOSFET 100 than the bottom side of the current spreading layer 112. In some embodiments, the bottom side of the first body region 117 is flush with bottom side of the current spreading layer 112.

The second body region 118 extends from the first surface 10a into the current spreading layer 112 and is adjacent to a first sidewall (the left side of the gate trench 115a in FIG. 1) of the gate trench 115a.

The first source region 119 is formed in the first body region 117, with a portion connecting the first portion 117a and the other portion connecting the second portion 117b. The first shielding region 121 adjoins the portion of the first source region 119 which is in the second portion 117b of the first body region. The first shielding region 121 is configured to reduce the effective electric field at the bottom corner of the gate trench 115a. The first shielding region 121 extends from the first surface 10a of the current spreading layer 112 into the current spreading layer 112, and extends deeply to at least the first body region 117. Specifically, the first shielding region 121 extends to and contacts the second portion 117b of the first body region 117.

The second source region 120 is formed in the second body region 118, and the second source region 120 is exposed to the first surface 10a of the current spreading layer 112. The second body region 118 is arranged between and adjoins the gate trench 115a and the second shielding region 122. The second shielding region 122 is formed in the current spreading layer 112 and is exposed to the first surface 10a.

In the embodiment of FIG. 1, the first portion 117a of the first body region 117 is in the vertical projection of the gate trench 115. The extension of the first portion 117a distanced from the second portion 117b stops before the vertical plane defined by the first sidewall of the gate electrode 115 which adjoins the second source region 120. In other words, the sidewall of the first portion 117a distanced from the second portion 117b has a distance from the vertical plane defined by the first sidewall of the gate electrode 115. In the embodiment of FIG. 1, a bottom side of the second shielding region 122 has a larger vertical distance from the first surface 10a than a bottom side of the gate trench 115a, for further reducing the electric field strength of the gate dielectric layer 114a to protect the gate dielectric layer 114a. In one embodiment, the bottom side of the second shielding region 122 has a distance of 0.1 μm to 0.5 μm to the bottom side of the gate trench 115a in the vertical direction normal to the first surface 10a of the current spreading layer 112.

In one embodiment, the second shielding region 122 is formed in the current spreading layer 112, i.e., the bottom side of the second shielding region 122 is above the bottom side of the current spreading layer 112. In other embodiments, the bottom side of the second shielding region 122 may extend through the current spreading layer 112 into the epitaxial layer 111. The distance of the bottom side of the second shielding region 122 from the first surface 10a may be set according to the spec requirements and is not limited by the embodiments of the present disclosure.

The trench MOSFET 100 includes an interlayer dielectric layer 126. The interlayer dielectric layer 126 covers at least the gate electrode 115 and the gate dielectric layer 114a.

The trench MOSFET 100 further includes a source contact 123 and a drain contact 124. The source contact 123 covers the first surface 10a. Specifically, the source contact 123 is disposed on the interlayer dielectric layer 126, the second source region 120, the first shielding region 121, and the second shielding region 122. Moreover, the source contact 123 has a portion extended to the gap 127 between the gate trench 115a and the first shielding region 121 to contact the first source region 119, for reducing the on resistance of the trench MOSFET. The portion of the source contact 123 filled in the gap 127 is insulated from the gate electrode 115 by the gate dielectric layer 114a, and contacts the first shielding region 121 and the first source region 119. The portion of the gate dielectric layer 114a on a second sidewall of the gate trench 115a has a first thickness. The second sidewall is opposite to the first sidewall of the gate trench 115. The portion of the gate dielectric layer 114a on the first sidewall of the gate trench 115 has a second thickness. The first thickness and the second thickness may be set according to the spec requirement. In one embodiment, the first thickness is greater than the second thickness.

The drain contact 124 is disposed on the substrate 101 of the trench MOSFET 100, and is in contact with the substrate 101.

In the embodiment of FIG. 1, when a positive voltage is applied to the gate electrode 115, a first channel (lateral channel) at the surface of the first body region 117 is formed. Meanwhile, a second channel (vertical channel) at the sidewall of the second body region 118 adjoining the gate trench 115a is formed. As a result, the trench MOSFET 100 is turned on. When the trench MOSFET 100 is on, electrons in the first source region 119 flow to the substrate 101 (drain region) through the first portion 117a (the first channel) of the first body region 117, the current spreading layer 112 and the epitaxial layer 111 (drift region) to form a first current path 11; and the electrons in the second source region 120 flow to the substrate 101 (drain region) through the second body region 118 (vertical channel region), the current spreading layer 112, and the epitaxial layer 111 (drift region) to form a second current path 12.

The embodiment of FIG. 1 enhances the conduction characteristics and reduces the conduction resistance of the trench MOSFET 100 by introducing a channel region on the sidewall of the gate trench 115a and a channel region under the bottom side of the gate trench 115a. The dual-channel regions achieve multiple conduction regions in a given area, maximizing the use of semiconductor materials and decreasing the die size.

In the embodiment of FIG. 1, the current spreading layer 112 further decreases the on resistance of the trench MOSFET 100.

When a zero voltage or a negative voltage is applied to the gate electrode 115, the trench MOSFET 100 is turned off. When the trench MOSFET 100 is reversely biased (off), a depletion layer is formed by the second shielding region 122, the first body region 117, the current spreading layer 112 and the epitaxial layer 111 (drift region). The second shielding region 122 and the first body region 117 work together to reduce the effective electric field at the bottom of the gate trench 115a to protect the gate dielectric layer 114a and to improve the reliability of the gate dielectric layer 114a.

In the embodiment of FIG. 1, the bottom side of the source contact 123 has a larger vertical distance from the first surface 10a than the gate trench 115a. The second shielding region 122 and the first body region 117 work together to reduce the effective electric field at the bottom of the gate trench 115a to protect the gate dielectric layer 114a and improve the reliability of the gate dielectric layer 114a.

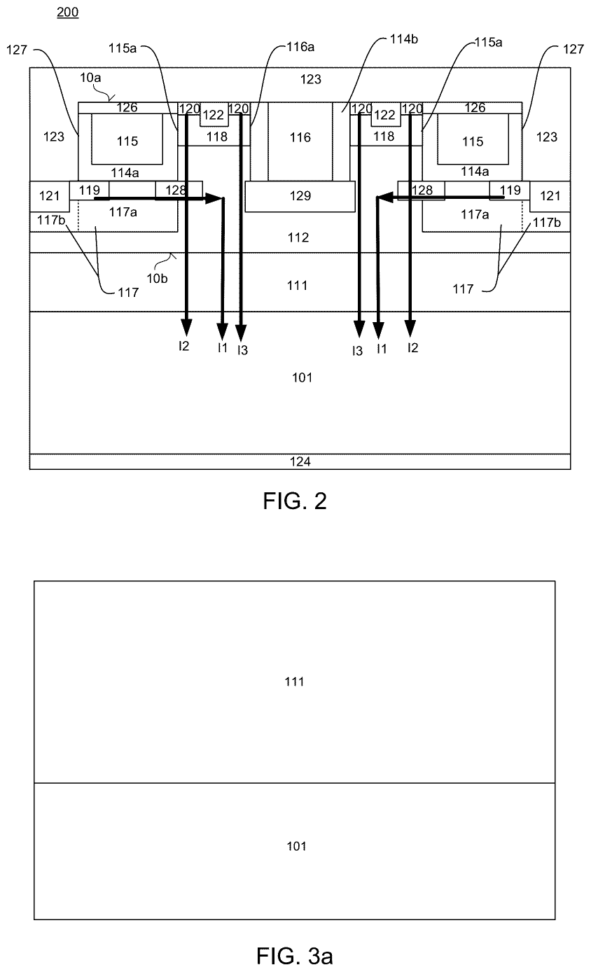

FIG. 2 shows a cross-sectional view of a trench MOSFET 200 in accordance with an embodiment of the present disclosure. As shown in FIG. 2, the trench MOSFET 200 comprises a substrate 101, an epitaxial layer 111 disposed on the substrate 101, and a current spreading layer 112 disposed on the epitaxial layer 111. The current spreading layer has a first surface 10a and a second surface 10b which is opposite to the first surface 10a in a vertical direction. The second surface 10b is in contact with the epitaxial layer 111. The substrate 101 serves as a drain region of the trench MOSFET 200. The epitaxial layer 111 serves as a drift region. The substrate 101, the epitaxial layer 111, and the current spreading layer 112 have a first conductivity type. In one embodiment, the substrate 101 is n-type with a high doping level, the epitaxial layer 111 is n-type with a low doping level, and the current spreading layer 112 is n-type with a high doping level, such that to reduce on-resistance of the trench MOSFET 200.

The trench MOSFET 200 includes a gate trench 115a and a source trench 116a. A gate electrode 115 fills in the gate trench 115a with a gate dielectric layer 114a in between to insulate the gate electrode 115 from the gate trench 115a. A source electrode 116 fills in the source trench 116a with a source dielectric layer 114b in between to insulate the source electrode 116 from the source trench 116a.

The gate trenches 115a are arranged on both sides of the source trench 116a and are symmetrically configured with respect to the source trench 116a. Both of the gate trenches 115a and the source trenches 116a extend from the first surface 10a of the current spreading layer 112 into the current spreading layer 112. The gate trench 115a and the source trench 116a are formed in the current spreading layer 112. Both of the bottom sides of the gate trench 115a and the source trench 116a have a smaller vertical distance from the first surface 10a than a thickness of the current spreading layer 112. The gate electrode 115 fills in the gate trench 115a and is insulated from the gate trench 115 by the gate dielectric layer 114a. The source electrode 116 fills in the source trench 116a. The sidewalls of the source electrode 116 are insulated from the current spreading layer 112 by the source dielectric layer 114b. The bottom side of the source electrode 116 contacts a doping region 129. In the embodiment of FIG. 2, the doping region 129 has a second conductivity type.

The depth of the gate trench 115a is greater than or equal to the depth of the source trench 116a.

The trench MOSFET 200 includes a first body region 117 and a second body region 118 both having a second conductivity type. The first body region 117 includes a first portion 117a and a second portion 117b which are connected to form the first body region 117. The first portion 117a is under the vertical projection of the gate trench 115a and adjoins the bottom of the gate trench 115a to protect the gate dielectric layer 114a at the bottom of the gate trench 115a. The second body region 118 is disposed between the gate trench 115a and the source trench 116a and adjoins the side wall of the gate trench 115a and the side wall of the source trench 116a.

In one embodiment, the bottom side of the first body region 117 has a larger vertical distance to the first surface 10a of the current spreading layer 112 than a bottom side of the current spreading layer 112, i.e., the first body region extends vertically into the epitaxial layer 111. In some embodiments, the bottom side of the first body region 117 has a smaller vertical distance to the first surface 10a than the bottom side of the current spreading layer 112.

The trench MOSFET 200 includes a first source region 119, a second source region 120, a buried layer 128, a first shielding region 121, a second shielding region 122, and a doped region 129. The first source region 119, the second source region 120 and the buried layer 128 have a first conductivity type. The first shielding region 121, the second shielding region 122 and the doped region 129 have a second conductivity type.

The first source region 119 is formed in the first body region 117 with a portion connecting the first portion 117a and the other portion connecting the second portion 117b. The first shielding region 121 is formed in the first body region 117, specifically in the second portion 117b of the first body region 117. A sidewall of the first shielding region 121 adjoins the first source zone 119. The second source region 120 is formed in the second body region 118. The second source region 120 has a sidewall adjoins the gate trench 115a and the other sidewall adjoins the source trench 116a. The second source region 120 is exposed to the first surface 10a of current spreading layer 112. The second shielding region 122 is formed in the second body region 118 and is exposed to a surface of the second source region 120. The second shielding region 122 contacts the second source region 120 and the second body region 118.

The buried layer 128 is formed at least in the first body region 117. In one embodiment, the buried layer 128 is formed in the first portion 117a, and has a sidewall flush with the sidewall of the first portion 117a which is distanced from the second portion 117b. In another embodiment, the buried layer 128 extends in a lateral direction through the side wall of the first portion 117a which is distanced from the second portion 117b, to the current spreading layer 112. The lateral direction is parallel to the first surface 10a, and is normal to the sidewalls of the gate trenches 115a and source trenches 116a. In the embodiment of FIG. 2, the buried layer 128 is configured to accelerate the electron flow from the lateral channel of the first body region 117 to the current spreading layer 112.

The doping region 129 is arranged under the source trench 116a, and adjoins the bottom of the source trench 116a. The doping region 129 contacts the source electrode 116. In one embodiment, a width of the doping region 129 is greater than the width of the source trench 116a in a lateral direction, and the bottom of the source trench 116a is fully covered by the doping region 129.

The trench MOSFET 200 includes an interlayer dielectric layer 126. The interlayer dielectric layer 126 covers at least the gate electrode 115 and the gate dielectric layer 114a.

The trench MOSFET 200 includes a source contact 123 and a drain contact 124. The source contact 123 contacts the first surface 10a of the current spreading layer 112 and fills in a gap 127, such that to contact the first source region 119 and the first shielding region 121 in the first body region 117. The portion of the source contact 123 in the gap 127 adjoins a sidewall of the gate trench 115a. The gate electrode 115 is insulated from the source contact 123 by the gate dielectric layer 114a.

The drain contact 124 is disposed on the substrate 101 and is in contact with the substrate 101.

In the present disclosure, the gate electrode 115 is insulated from the gate trench 115a by the gate dielectric layer 114a. The portion of the gate dielectric layer 114a between the gate electrode 115 and the current spreading layer 112 has a first thickness which could be adjusted for regulating the threshold voltage of the trench MOSFET 200. The gate dielectric layer 114a between the gate electrode 115 and the source contact 123 serves as an insulating layer and has a second thickness. In one embodiment, the second thickness is greater than 100 nanometers. The source electrode 116 is insulated from the current spreading layer 112 by the source dielectric layer 114b. The portion of the source dielectric layer 114b between the source electrode 116 and the second body region 118 has a third thickness, which could be adjusted for regulating a forward conduction voltage of a diode in the channel region of the second body region 118.

In the embodiment of FIG. 2, when a positive voltage is applied to the gate electrode 115, a first channel (lateral channel) at the surface of the first body region 117 is formed. Meanwhile, a second channel at the surface of the second body region 118 is formed. As a result, the trench MOSFET 200 is turned on. When the trench MOSFET 100 is on, electrons in the first source region 119 flow to the substrate 101 (drain region) through the first portion 117a (the lateral channel) of the first body region 117, the buried layer 128, the current spreading layer 112 and the epitaxial layer 111 (drift region) to form a first current path 11. The buried layer 128 accelerate the electron flowing. The electrons in the second source region 120 flow to the substrate 101 (drain region) through the second body region 118 (vertical channel region), the current spreading layer 112, and the epitaxial layer 111 (drift region) to form a second current path 12.

When a zero voltage or a negative voltage is applied to the gate electrode 115, the trench MOSFET 200 is turned off. When the trench MOSFET 200 is reversely biased (off), a depletion layer is formed by the second shielding region 122, the first body region 117, the current spreading layer 112 and the epitaxial layer 111 (drift region). The second shielding region 122 and the first body region 117 work together to reduce the effective electric field at the bottom of the gate trench 115a to protect the gate dielectric layer 114a and to improve the reliability of the gate dielectric layer 114a.

The source electrode 116 and the portion of the source dielectric layer 114b between the source electrode 116 and the second body region 118 form the diode in the channel region of the second body region 118 when the trench MOSFET 200 is on. Specifically, the portion of the second body region 118 along the source dielectric layer 114b is reversed to form the channel for flowing the electrons when the trench MOSFET 200 is on. The electrons in the second source region 120 flow to the substrate 101 through this channel and the current spreading layer 112 to form a third current path 13. When the trench MOSFET 200 is on, the diode formed by the source contact 123, the source electrode 116 and the third current path could be conducted before a body diode of the trench MOSFET 200 by adjusting the third thickness of the source dielectric layer 114b, such that to eliminate the bipolar degeneration effect.

The current spreading layer 112 in the embodiments of the present disclosure reduces the on-resistance of the trench MOSFET 200.

The embodiment of FIG. 2 enhances the conduction characteristics and reduces the conduction resistance of the trench MOSFET 200 by introducing a channel region on the sidewall of the gate trench 115a, a channel region under the bottom side of the gate trench 115a, and a channel region along the sidewall of the source trench 116a. The three channel regions achieve multiple conduction regions in a given area, maximizing the use of semiconductor materials and decreasing the die size.

The embodiments of the present disclosure introduce a diode in the channel region which is controlled to be conducted before the body diode of the trench MOSFET by adjusting the thickness of the source dielectric layer 114b. The diode in the channel region is a unipolar device (only electrons flow) and helps eliminating the bipolar degeneration effect. Furthermore, the diode in the channel region is a unipolar device which has almost no minority carriers during reverse mode. As a result, the reverse recovery characteristic of the trench MOSFET 200 is improved.

The embodiments of the present disclosure introduce the buried layer 128 for accelerating the current flowing. In addition, when the trench MOSFET 200 is shorted and is heating up, the resistance of the buried layer 128 increases, such that the short current could be reduced.

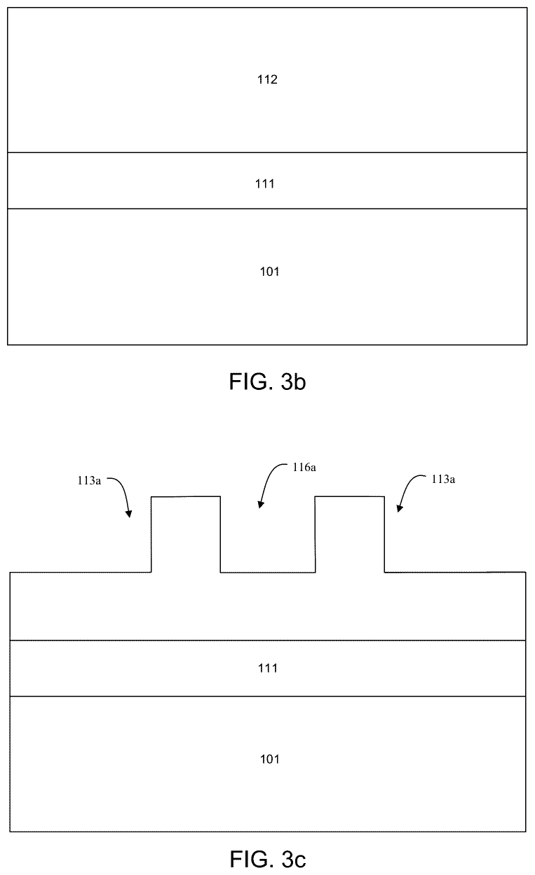

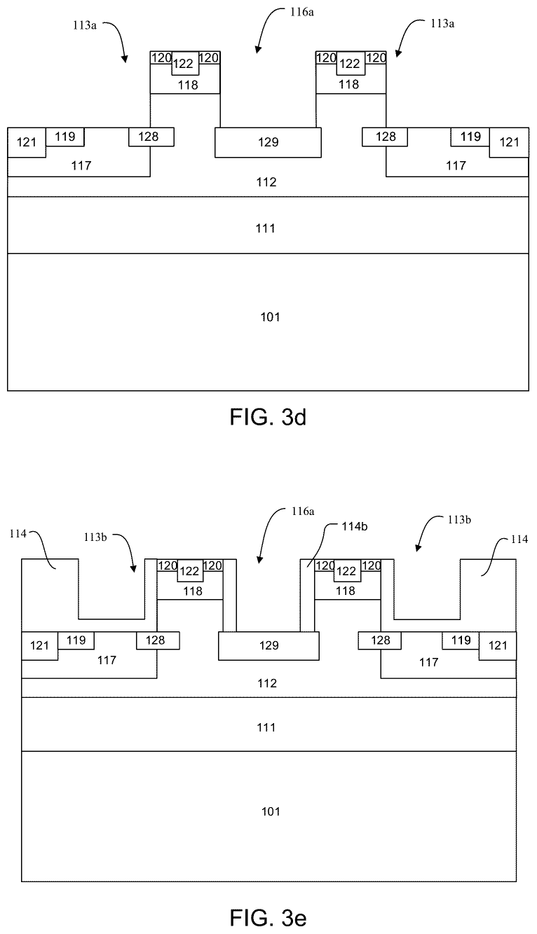

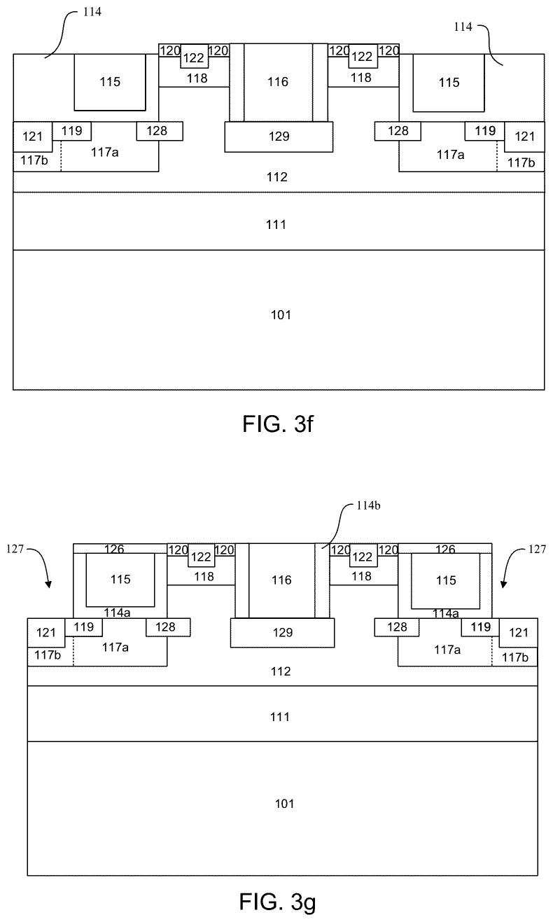

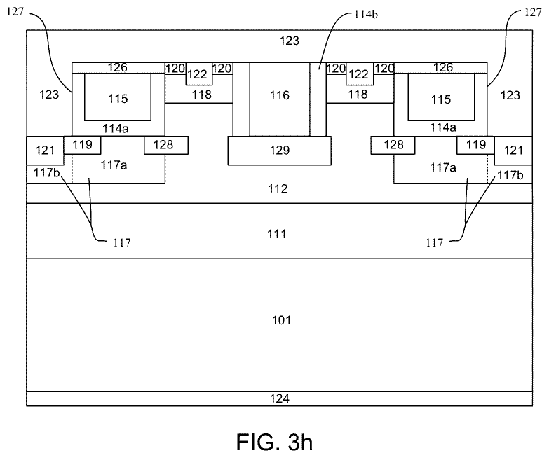

FIGS. 3a to 3h illustrate cross-sectional views of a trench MOSFET at different steps of the manufacturing process in accordance with an embodiment of the present disclosure.

As shown in FIG. 3a, the epitaxial layer 111 is formed on the substrate 101.

In the embodiment of FIG. 3a, the epitaxial layer 111 is formed by an epitaxial layer growth process. The substrate 101 and the epitaxial layer 111 have a first conductivity type. The substrate 101 serves as a drain region of the MOSFET and the epitaxial layer 111 serves as a drift region. In one embodiment, the substrate 101 is n-type with a high doping level, the epitaxial layer 111 is n-type with a low doping level. In some embodiments, the substrate 101 may be a silicon carbide (SiC) substrate.

In FIG. 3b, the current spreading layer 112 is formed on the epitaxial layer 111.

In the embodiment of FIG. 3b, dopants of the first conductivity type are implanted into the epitaxial layer 111 by ion implantation process to form the current spreading layer 112 on the epitaxial layer 111, i.e., an upper layer of the epitaxial layer 111 is turned into the current spreading layer 112. By controlling the ion implantation process, such as the implanting strength and dopants concentration, a desired depth and doping concentration of the current spreading layer 112 could be achieved. In one embodiment, the current spreading layer 112 is n-type with a high doping level. In some embodiments, the current spreading layer 112 may be formed by other known processes, such as epitaxial growth process.

In FIG. 3c, first trenches 113a and the source trenches 116a are formed.

In the embodiment of FIG. 3c, firstly, a mask is formed and patterned by a photolithography process. Then the current spreading layer 112 is etched to form the first trenches 113a and the source trenches 116a in the current spreading layer 112. Some of the first trenches 113a form the gate trenches 115a and the rest of the first trenches 113a form the gaps 127 later. In one embodiment, the etching process may be a dry etching process, such as ion-mill etching, plasma etching, reactive ion etching, laser ablation. After the etching process, the mask is removed. In one embodiment, the mask may be a photoresist mask.

In the embodiments of the present disclosure, each source trench 116a has two first trenches 113a arranged symmetrically on both sides. In one embodiment, the first trenches 113a and the source trenches 116a have the same depth.

In FIG. 3d, a first ion implantation process is performed to form the first body regions 117 and the second body regions 118, both of which have a second conductivity type.

In the embodiment of FIG. 3d, firstly, a mask is formed and patterned on the current spreading layer 112 by a photolithography process. Then dopants of the second conductivity type are implanted through the openings of the mask to form the first body region 117 and the second body region 118 in the current spreading layer 112 by the first ion implantation process. The first body region 117 are formed at the bottoms of the first trenches 113a. The second body region 118 are formed in the mesas between the first trenches 113a and the source trenches 116a. By controlling the ion implantation process, such as the implanting strength and dopants concentration, desired depths and doping concentrations of the first body regions 117 and second body regions 118 could be achieved. The mask is removed after forming the first body regions 117 and the second body regions 118.

In a following step, a second ion implantation process is performed to form the first source regions 119, the second source regions 120 and the buried layers 128, all of which have a first conductivity type.

Specifically, a mask is formed and patterned by a photolithography process on a surface of the current spreading layer 112. Then by applying the second ion implantation process, the first source regions 119 and the buried layers 128 are formed in the first body region 117, and the second source regions 120 are formed in the second body region 118. The first source regions 119 are exposed to the surface of the first body regions 117. The second source regions 120 are exposed to the surface of the second body regions 118. The buried layers 128 diffuse laterally in a following anneal step, such that the buried layers 128 are laterally extended into the current spreading layer 112 adjoining the side wall of the first body region 117. Consequently, the buried layers 128 are under one of sidewalls of each first trench 113a. In other words, each of the buried layers 128 has a portion in the first body region 117 and the other portion in the current spreading region 112.

In a following step, a third ion implantation process is performed to form the first shielding regions 121, the second shielding regions 122 and the doped regions 129, all of which have the second conductivity type.

Specifically, a mask is firstly formed and patterned by a photolithography process on a surface of the current spreading layer 112. Then by applying the third ion implantation process, the first shielding regions 121 are formed in the first body regions 117, the second shielding regions 122 are formed in the second source region 120, and the doped regions 129 are formed at the bottom of the source trench 116a. Each of the first shielding regions 121 adjoins the first source region 119 and is exposed to the surface of the first body region 117. The second shielding regions 122 are formed in the second source regions 120 and extended through the second source regions 120 to the second body regions 118. The doping region 129 has an approximately same width with the source trench 116a during the third ion implantation process. In a following anneal step, the doping region 129 is laterally diffused, and consequently has a larger width than the source trench 116a.

In FIG. 3e, dielectric layers are formed and etched.

Specifically, the dielectric layers 114 are formed to fill the first trenches 113a and the source trenches 116a, and meanwhile cover the current spreading layer 112. In one embodiment, the dielectric layers 114 include silicon oxide layers.

Then, an etch process is applied to remove the dielectric layer 114 disposed on the current spreading layer 112. Subsequently, the dielectric layers 114 in the first trenches 113a are etched to form the second trench 113b, which are later served as the gate trenches 115a. The dielectric layer 114 that is remained within the first trenches 113a are partly adopted as the gate dielectric layers 114a and partly etched away to form the gaps 127 in a subsequent process.

The dielectric layers 114 in the source trenches 116a are also etched away with a layer remained to cover the sidewalls of the source trench 116a. In other embodiments, the dielectric layers in the source trenches 116a are all etched away, and an oxidation process is performed to form the source dielectric layers 114b on the sidewalls of the source trenches 116a.

In FIG. 3f, the gate electrode 115 and the source electrode 116 are formed.

Specifically, conductor layers are formed above the second trenches 113b, the source trenches 116a, and the current spreading layer 112, by a low-pressure chemical vapor deposition, for example.

Then, etching or chemical mechanical planarization is applied to remove the portion of the conductor layers on the current spreading layer 112 such that the top of the conductor layers in the second trenches 113b are lower than the top of the current spreading layer 112. The conductor layer in the second trench 113b forms the gate electrode 115. Meanwhile the top of the conductor layer in the source trenches 116a are made flush with the top of the current spreading layer 112, and the conductor layers in the source trenches 116a serve as the source electrodes 116.

In FIG. 3g, an interlayer dielectric layer 126 is formed.

Specifically, the interlayer dielectric layer 126 is formed on top of the current spreading layer 112 by a deposition process, which is further chemo-mechanically planarized to obtain a planar surface.

The interlayer dielectric layer 126 is etched, leaving layers covering the top of the gate electrode 115. The rest of the interlayer dielectric layer 126 are etched away to expose the source electrodes 116, the source dielectric layers 114b, the second source regions 120 and the second shielding regions 122.

The etching process continues to remove the dielectric layers 114 within the first trenches 113a to form the gaps 127. The first shielding region 121 in the first body region 117 and at least a portion of the first source region 119 are exposed after etching. After forming the gaps 127, the remaining dielectric layers in the first trenches 113a form the gate dielectric layers 114a. The gate dielectric layers 114a and the gate electrodes 115 are arranged in the first trenches 113a. Each of the gaps 127 is adjacent to the respective first trench 113a.

In FIG. 3h, the source contact 123 and the drain contact 124 are formed. the source contact 123 is disposed on the current spreading layer 112, and is in contact with the second source regions 120 and the second doped regions 120. Furthermore, the source contact 123 has portions filling in the gap 127, and contacting the first source regions 119 and the second doped regions 120. The portions of the source contact 123 in the gaps 127 are adjacent to the gate trenches 115a. Each of the gate electrodes 115 is insulated from the portion of the source contact 123 in the neighboring gap 127 by the gate dielectric layer 114a.

In the embodiments of the present disclosure, the source contact 123, the source electrode 116, the gate electrode 115, and the drain contact 124 may include electrically conductive material, like aluminum alloy or copper, etc.

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as well as variations and modifications thereof, which would occur to persons skilled in the art upon reading the foregoing description.

1. A semiconductor device, comprising:
a current spreading layer having a first surface and a second surface opposite to the first surface along a vertical direction;
a gate trench formed in the current spreading layer, the gate trench vertically extending from the first surface of the current spreading layer into the current spreading layer;
a gate electrode filling in the gate trench with a gate dielectric layer in between for insulation;
a first body region beneath the gate trench and in contact with the gate trench;
a first source region formed in the first body region;
a second body region extending from the first surface of the current spreading layer into the current spreading layer and adjoining a first sidewall of the gate trench; and
a second source region formed in the second body region, the second source region adjoining the first sidewall of the gate trench.

2. The semiconductor device of claim 1, wherein the first body region comprises:
a first portion under a vertical projection of the gate trench; and
a second portion adjoins the first portion under a second sidewall of the gate trench.

3. The semiconductor device of claim 2, wherein the first portion of the first body region covers a part of a bottom of the gate trench, leaving at least a portion of the gate dielectric layer at the bottom of the gate trench directly contacting the current spreading layer.

4. The semiconductor device of claim 2, wherein a width of the first portion of the first body region is smaller than a width of the gate trench in a lateral direction normal to the sidewalls of the gate trench.

5. The semiconductor device of claim 2, wherein the first source region is formed in both the first portion and the second portion of the first body region.

6. The semiconductor device of claim 1, further comprising:
a first shielding region vertically extending from the first surface of the current spreading layer to contact the first source region and the first body region, wherein a depth of the first shielding region with respect to the first surface of the current spreading layer is larger than a depth of the gate trench with respect to the first surface of the current spreading layer.

7. The semiconductor device of claim 1, further comprising:
a second shielding region vertically extending from the first surface of the current spreading layer into the current spreading layer, wherein a depth of the second shielding region with respect to the first surface of the current spreading layer is larger than a depth of the gate trench with respect to the first surface of the current spreading layer.

8. The semiconductor device of claim 1, wherein the current spreading layer, the first source region and the second source region have a first conductivity type, the first body region and the second body region have a second conductivity type.

9. The semiconductor device of claim 8, further comprising:
a substrate of the first conductivity type; and
an epitaxial layer of the first conductivity type in contact with the substrate, wherein the current spreading layer is in contact with the epitaxial layer by the second surface.

10. The semiconductor device of claim 9, further comprising:
a source contact electrically connected to the first source region and the second source region; and
a drain contact electrically connected to the substrate.

11. The semiconductor device of claim 1, wherein a thickness of the gate dielectric layer portion covering the first sidewall of the gate trench is smaller than a thickness of the gate dielectric layer portion covering a second sidewall of the gate trench, and wherein the first sidewall and the second sidewall are on opposite sides of the gate trench.

12. A semiconductor device, comprising:
a current spreading layer having a first surface and a second surface opposite to the first surface along a vertical direction;
a plurality of gate trenches formed in the current spreading layer, the plurality of gate trenches vertically extending from the first surface of the current spreading layer into the current spreading layer;
a plurality of gate electrodes filling in the plurality of gate trenches respectively with a gate dielectric layer in between for insulation;
a plurality of first body regions beneath the plurality of gate trenches respectively, wherein each one of the plurality of first body regions is in contact with the respective one of the plurality of gate trenches;
a plurality of first source regions formed in the plurality of first body region respectively;
a plurality of second body regions extending from the first surface of the current spreading layer into the current spreading layer, wherein each one of plurality of second body regions adjoins a first sidewall of the respective one of the plurality of gate trenches;
a plurality of second source regions formed in the plurality of second body regions respectively, wherein each one of the plurality of second source regions adjoins the first sidewall of the respective one of the plurality of gate trenches;
a plurality of source trenches extending from the first surface of the current spreading layer into the current spreading layer, wherein each one of the plurality of source trenches is formed between two neighboring gate trenches;
a plurality of source electrodes filling in the plurality of source trenches respectively, wherein each one of the plurality of source electrodes is insulated from sidewalls of the respective one of the plurality of source trenches with source dielectric layers; and
a plurality of doping regions under the plurality of source trenches respectively.

13. The semiconductor device of claim 12, wherein each one of the plurality of first body regions comprises:
a first portion under a vertical projection of the respective one of the plurality of gate trenches; and
a second portion adjoins the first portion under a second sidewall of the respective one of the plurality of gate trenches.

14. The semiconductor device of claim 13, wherein each one of the plurality of first source regions is formed in both the first portion and the second portion of the respective one of the plurality of first body regions.

15. The semiconductor device of claim 13, further comprising:
a plurality of first shielding regions formed respectively in the second portion of the respective one of the plurality of first body regions, wherein each one of the plurality of first shielding regions adjoins the respective one of the plurality of first source regions.

16. The semiconductor device of claim 12, further comprising:
a plurality of second shielding regions formed in the plurality of second source regions and the plurality of second body regions respectively, each one of the plurality of second shielding regions vertically extending from a surface of the respective one of the plurality of source regions into the respective one of the plurality of second body regions.

17. The semiconductor device of claim 12, further comprising a plurality of buried layers formed in the plurality of first body regions respectively, each one of the plurality of buried layers extending in a lateral direction into the current spreading layer, wherein the lateral direction is normal to sidewalls of the gate trenches.

18. The semiconductor device of claim 12, wherein the current spreading layer, the plurality of first source regions and the plurality of second source regions have a first conductivity type, the plurality of first body regions and the plurality of second body regions have a second conductivity type.

19. A semiconductor device manufacturing method, comprising:
forming an epitaxial layer on a substrate;
forming a current spreading layer on the epitaxial layer;
forming first trenches and source trenches in the current spreading layer;
forming first body regions and second body regions, wherein the first body regions are formed in the mesas between the neighboring first trenches and source trenches, and the second body regions are formed at the bottom of the first trenches;
forming first source regions in the first body regions, second source regions in the second body regions, and buried layers at the bottom of the source trenches;
forming dielectric layers on top of a surface of the semiconductor device which is distanced from the substrate;
etching the dielectric layers, wherein the dielectric layers at the bottom of the source trenches are etched away to expose the doping regions, and the dielectric layers on the sidewalls of the source trenches server as the source dielectric layers, and wherein the dielectric layers in the first trenches are etched to form the gate trenches, and the dielectric layers in the gate trenches serve as the gate dielectric layers;
forming gate electrodes in the gate trenches and forming source electrodes in the source trenches;
forming interlayer dielectric layers to cover the gate electrodes and the gate dielectric layers;
forming a source contact to electrically connect the first source regions and the second source regions; and
forming a drain contact to electrically connect the substrate.

20. The manufacturing method of claim 19, further comprising:
forming first shielding regions in the first body regions; and
forming second shielding regions in the second body regions.
